(19) United States
(12) Patent Application Publication
(10) Pub. No.: US 2002/0119595 A1
(43) Pub. Date: Aug. 29, 2002

(54) Semiconductor package using tape circuit board with a groove for preventing encapsulant from overflowing and manufacturing method thereof

(75) Inventors: Shin Kim, Chungcheongnam-do (KR); Se-Yong Oh, Seoul (KR); Jung-Jin Kim, Chungcheongnam-do (KR); Tae-Gyeong Chung, Kyungki-do (KR)

Correspondence Address: MARGER JOHNSON & McCOLLOM, P.C., 1030 S.W. Morrison Street, Portlant, OR, 97205, US

(73) Assignee: Samsung Electronics Co., Ltd., Suwon City (KR)

(21) Appl. No.: 10/083,755

(22) Filed: Feb. 25, 2002

(30) Foreign Application Priority Data
Feb. 24, 2001 (KR) 2001-9468

(51) Int. Cl. H01L 21/44; H01L 23/02

(52) U.S. Cl. 438/106; 257/678

(57) ABSTRACT

A semiconductor package using a tape circuit board with a groove for preventing an encapsulant from overflowing and a manufacturing method for this package are disclosed. The semiconductor package comprises a semiconductor chip with a plurality of electrode pads formed on an active surface thereof; a tape circuit board including an insulating tape with a window formed in a center thereof; circuit patterns formed on an upper surface of the insulating tape, the circuit patterns having a plurality of board pads adjacent the window and a plurality of conductive ball pads connected to the board pads; and a protection layer overlying the upper surface of the insulating tape, leaving the board pads and the conductive ball pads uncovered. The active surface of the chip is attached to a lower surface of the insulating tape and the electrode pads are exposed through the window and electrically connected to board pads. Further, a groove extends around the window to prevent encapsulant overflow by partially removing the protection layer so that the groove does not expose the circuit patterns.

This application relies for priority upon Korean Patent Application No. 2001-9468, filed on Feb. 24, 2001, the contents of which are herein incorporated by reference in their entirety.

### BACKGROUND OF THE INVENTION

1. Field of the Invention

The present invention relates to semiconductor packaging technology and, more particularly, to a semiconductor package using a tape circuit board, and a manufacturing method for this package.

2. Description of the Related Art

Recent trends in electronics development have been toward lighter weight, miniaturization, high speed, multi-functionality, and improved quality and reliability. In line with these trends, ball grid array (BGA) packages have been developed. Compared to the conventional plastic package, the BGA package has the advantage of reduced mounting area on a motherboard and improved electronic characteristics.

While the conventional plastic packages employ a lead frame, the BGA package employs a printed circuit board. Since the solder balls and the semiconductor chips do not share the same surface of the printed circuit board, the BGA can achieve a high mounting density. However, because the printed circuit board requires an area for mounting the semiconductor chip, it has a greater size than the chip itself.

In order to mitigate this drawback, a so-called chip scale package (CSP), which has the same size or is only slightly larger than the chip has been introduced.

Many semiconductor manufacturers in countries such as U.S., Japan, or Korea are developing various types of CSPs. Typically, CSP uses a tape circuit board comprising a flexible polyimide tape and circuit patterns formed on the tape. Normally, in this type of CSP, the semiconductor chip is electrically connected to the tape circuit board by using a beam lead-bonding method or a wire-bonding method.

FIG. 1 is a cross-sectional view of a conventional BGA package 100. As shown in FIG. 1, a semiconductor chip 10 is attached to the lower surface of a tape circuit board 20. A window 22 is formed on the tape circuit board 20 in the center, and bonding pads 12 of the chip 10 are exposed through the window 22. The chip 10 is electrically connected to the tape circuit board 20 by bonding wires 40 attached to bonding electrode pads 12 of the chip 10 and board pads 24 of the tape circuit board 20 running through the window 22. The window 22, including the bonding wires 40 and the side surfaces of the chip 10, are encapsulated within a liquid encapsulant, thereby forming a first encapsulation body 51 and a second encapsulation body 53. That is, the first encapsulation body 51 encapsulates the window 22 and the second encapsulation body 53 encapsulates the side surfaces of the chip 10.

The tape circuit board 20 comprises a polyimide tape 21 with the window 22 in the center, and the circuit patterns 23 formed on the upper surface of the polyimide tape 21. The circuit patterns 23 are formed around the window 22, and include the board pads 24 for connection to the electrode pads 12 of the chip 10 and solder ball pads 26 for receiving solder balls 60. Except for the board pads 24 and the solder ball pads 26, the upper surface of the polyimide tape 21 is coated with a protection layer 25.

Wire loops formed by the bonding wires 40 extrude from the upper surface of the tape circuit board 20. Therefore, the first encapsulation body 51 for encapsulating the window 22 must swell out to enclose the wire loops.

The liquid encapsulant for forming the first encapsulation body 51 may overflow and contaminate the closest solder ball pads 26a. This causes failures in the attachment of the solder ball 60a on the contaminated solder ball pad 26a or in the electrical connection between the solder ball 60a and the contaminated solder ball pad 26a.

### SUMMARY OF THE INVENTION

The present invention contemplates the prevention of encapsulant overflow during molding.

According to one embodiment of the present invention, the present invention provides a semiconductor package comprising: a semiconductor chip with a plurality of electrode pads formed on an active surface thereof; a tape circuit board comprising: an insulating tape with a window formed in a center thereof; circuit patterns formed on an upper surface of the insulating tape, the circuit patterns having a plurality of board pads adjacent the window and a plurality of conductive ball pads connected to the board pads; and a protection layer overlying the upper surface of the insulating tape, leaving the board pads and the conductive ball pads uncovered. The active surface of the chip is attached to a lower surface of the insulating tape and the electrode pads are exposed through the window and electrically connected to board pads. Further, a groove extends around the window to prevent encapsulant overflow by partially removing the protection layer so that the groove does not expose the circuit patterns.

According to another embodiment, the semiconductor package comprises a semiconductor chip with a plurality of center electrode pads formed along the center of the active upper surface and a tape circuit board. The tape circuit board comprises a polyimide tape with a window formed in the center; circuit patterns formed on the upper surface of the polyimide tape, the circuit patterns having a plurality of board pads around the window and a plurality of solder ball pads connected to the board pads; and a protection layer formed on the upper surface of the polyimide tape except for the board pads and the solder ball pads, wherein the active surface of the chip is attached to the lower surface of the polyimide tape and the electrode pads are exposed through the window. The semiconductor package further comprises a plurality of bonding wires for electrically connecting the electrode pads to the board pads through the window; an encapsulation body formed by encapsulating the window and the board pads with a liquid encapsulant; and a plurality of solder balls formed on the solder ball pads. A groove is formed along the window by incompletely removing the protection layer so that the groove does not expose the circuit patterns.

The tape circuit board of the present invention further comprises an elastomer on the lower surface of the polyimide tape, and the active upper surface of the chip is attached to the elastomer.

In yet another embodiment, the present invention also provides a method for manufacturing a semiconductor package using a tape circuit board with a groove for preventing an encapsulant from overflowing. The method comprises (A) manufacturing a tape circuit board, comprising the sub-steps of: (a1) preparing a polyimide tape having a window formed in the center, and circuit patterns formed on the upper surface, the circuit patterns having a plurality of board pads around the window and a plurality of solder ball pads connected to the board pads; (a2) forming a protection layer on the upper surface of the polyimide tape except for the board pads and the solder ball pads, wherein a groove is formed along the window by incompletely removing the protection layer so that the groove does not expose the circuit patterns; and (a3) attaching an elastomer to the lower surface of the polyimide tape; (B) attaching the active surface of a semiconductor chip to the lower surface of the elastomer so that center electrode pads formed along the center of the active surface of the chip are exposed through the window; (C) electrically connecting the electrode pads to the board pads with bonding wires; (D) forming an encapsulation body by encapsulating the window and the board pads with a liquid encapsulant, thereby protecting the electrode pads and the bonding wires from external environments; and (E) forming solder balls on the solder ball pads.

### BRIEF DESCRIPTION OF THE DRAWINGS

These and other objects, features and advantages of the present invention will be readily understood with reference to the following detailed description thereof provided in conjunction with the accompanying drawings, wherein like reference numerals designate like structural elements, and, in which:

FIG. 1 is a cross-sectional view of a conventional ball grid array package using a tape circuit board with a window in the center;

FIG. 2 is an exploded isometric view of a tape circuit board with a groove for preventing the encapsulant from overflowing in accordance with the present invention;

FIG. 3 is a cross-sectional view taken along the line I-I in FIG. 2;

FIG. 4 is a cross-sectional view of a semiconductor package using the tape circuit board of FIGS. 2 and 3 in accordance with the present invention;

FIGS. 5 to 10 show each step of a manufacturing method of a tape circuit board in accordance with a first embodiment of the present invention:

FIG. 5 is a cross-sectional view of preparing a polyimide tape having circuit patterns on the upper surface;

FIG. 6 is a cross-sectional view of forming a protection layer on the upper surface of the polyimide tape;

FIG. 7 is a cross-sectional view of a first exposing region of the protection layer, which will be a groove;

FIG. 8 is a cross-sectional view showing a second exposing region of the protection layer, which is disposed above the solder ball pads;

FIG. 9 is a cross-sectional view showing the development of the protection layer, thereby forming a groove and via holes exposing the solder ball pads; and

FIG. 10 is a cross-sectional view showing the formation of a plating layer;

FIGS. 11 to 14 show each step of a manufacturing method of a tape circuit board in accordance with a second embodiment of the present invention:

FIG. 11 is a cross-sectional view showing the formation of a protection layer on the upper surface of a polyimide tape except for on a groove region;

FIG. 12 is a cross-sectional view showing exposing regions of the protection layer, which are disposed above the solder ball pads;

FIG. 13 is a cross-sectional view showing the development of the protection layer, thereby forming via holes that expose the solder ball pads; and

FIG. 14 is a cross-sectional view showing the formation of a plating layer.

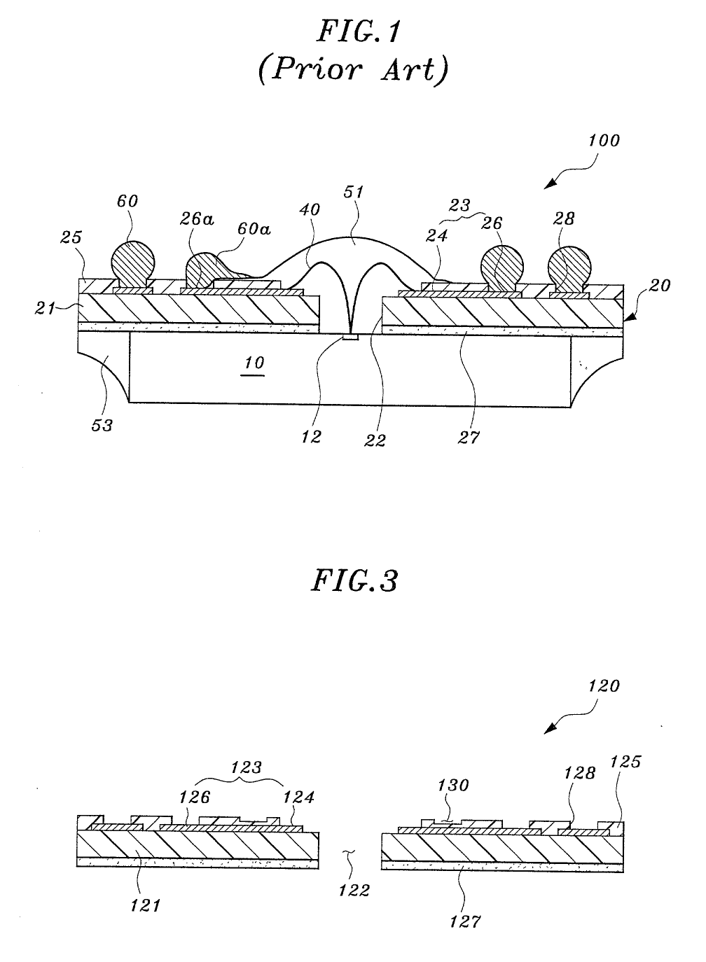

### DETAILED DESCRIPTION OF THE PREFERRED EMBODIMENTS

Preferred embodiments of the present invention will be described below with reference to the accompanying drawings.

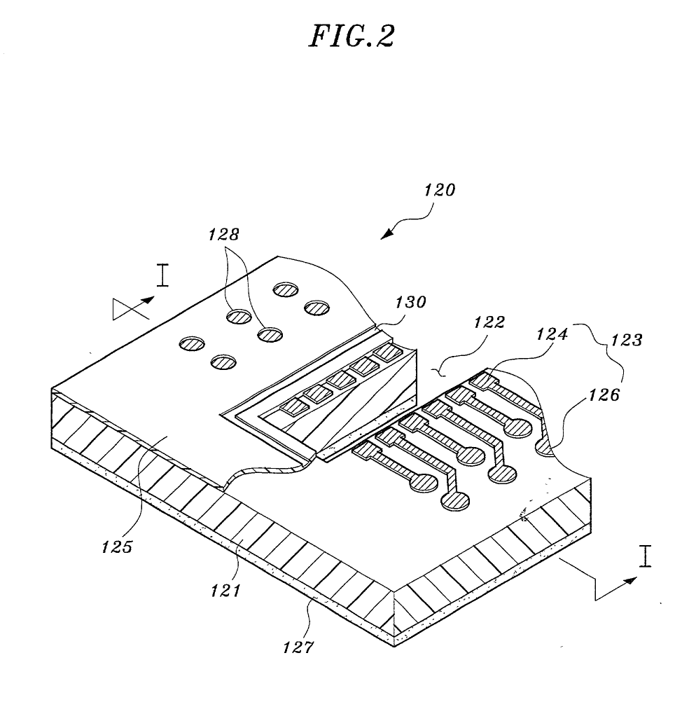

FIG. 2 is an exploded perspective view of a tape circuit board 120 with a groove 130 for preventing the encapsulant from overflowing in accordance with the present invention. FIG. 3 is a cross-sectional view taken along the line I-I in FIG. 2.

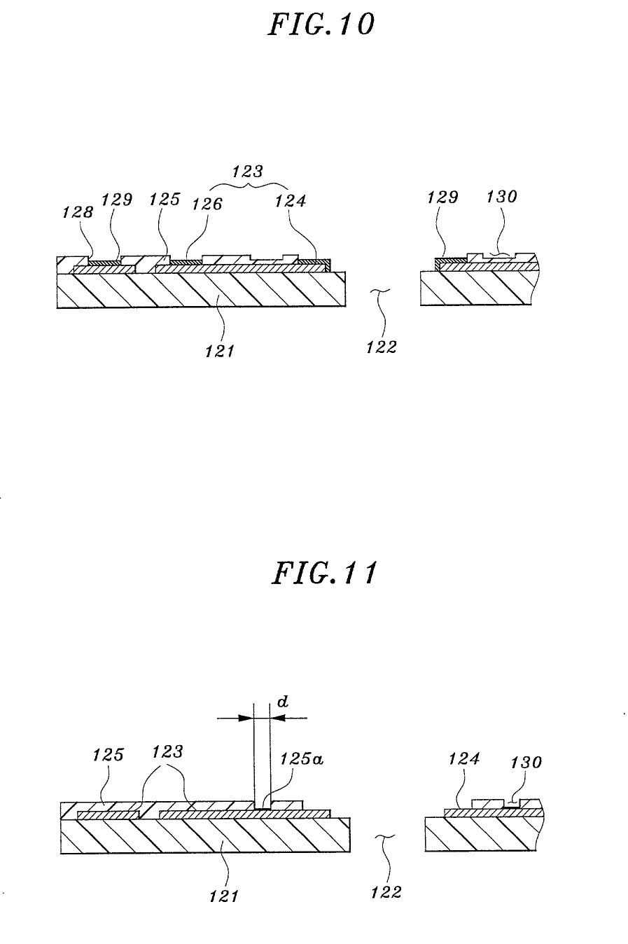

With reference to FIGS. 2 and 3, the tape circuit board 120 comprises an insulating tape, such as a polyimide tape 121 with a window 122 in the center and circuit patterns 123 formed on the upper surface of the polyimide tape 121. The circuit patterns 123 have board pads 124 formed around the window 122 and solder ball pads 126 connected to the board pads 124. In order to prevent the oxidation of the circuit patterns 123, the upper surface of the polyimide tape 121 except for the board pads 124 and the solder ball pads 126 is coated with a protection layer 125. The protection layer 125 is made of photo solder resist (PSR). The board pads 124 and the solder ball pads 126 are coated with a plating layer (129 in FIG. 10). The plating layer is made of a metal such as Ni or Au. An elastomer 127 is attached to the lower surface of the polyimide tape 121.

According to one embodiment of the present invention, the polyimide tape 121 is approximately 75 μm thick. The circuit patterns 123 are formed by attaching a Cu or an Au foil approximately 18 μm thick. The protection layer 125 on the upper surface of the polyimide tape 121 is approximately 25 μm to 45 μm thick, and the elastomer 127 is approximately 50 μm thick.

A groove 130 is formed around the window 122 by partially removing, for example, half-etching the protection layer 125. The groove 130 prevents the encapsulant from overflowing. At this time, the circuit patterns 123 are not exposed by the groove 130.

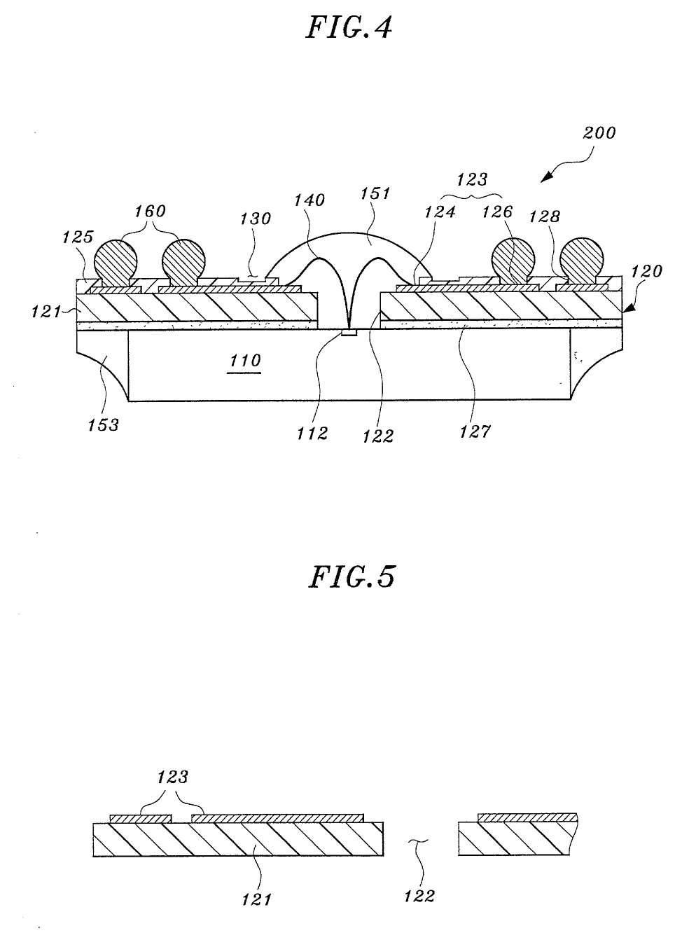

FIG. 4 shows a semiconductor package 200 using the above-described tape circuit board 120. As shown in FIG. 4, the active surface of a semiconductor chip 110 is attached to the lower surface of the elastomer 127 so that electrode pads 112 of the semiconductor chip 110 are exposed through the window 122 of the tape circuit board 120. The semiconductor chip 110 is center pad type chip with the electrode pads 112 in the center of the active surface. The semiconductor chip 110 is approximately 450 mm thick.

The electrode pads 112 of the semiconductor chip 110 are electrically connected to the board pads 124 of the tape circuit board 120 by bonding wires 140. Preferably, the bonding wire 130 is made of Au.

In order to protect the electrode pads 112, board pads 124, and bonding wires 140 from external stresses, the window 122 and the board pads 124 are encapsulated with a encapsulant, thereby forming a first encapsulation body 151. Thermosetting silicon resin with great adhesion and high thermal stress absorption is primarily used as the encapsulant. Conventional epoxy resin may also be used. An encapsulant with a predetermined viscosity is supplied to the window 122 and the board pads 124 by potting, and is hardened. A dispensing method that dispenses the liquid encapsulant through a syringe is used as the potting. The side surfaces of the semiconductor 110 are encapsulated with the liquid encapsulant, thereby forming a second encapsulation body 153.

A conductive ball, e.g., solder ball 160 is attached to the solder ball pads 126 through via holes 128 formed on the protection layer 125. After applying flux to the solder ball pads 126 exposed through the via holes 128, the solder balls 160 are mounted on the solder ball pads 126. The solder balls 160 are attached to the solder ball pads 126 by reflowing. Instead of attaching the solder balls 160, Ni or Au bumps may be formed.

Since the package 200 is mounted on an external circuit board (not shown) via the solder balls 160 of the packages, the solder balls 160 should be of greater height than the first encapsulation body 151. Such a structure prevents contact by the first encapsulation body 151 with the external circuit board. The height of the first encapsulation body 151 should be determined in consideration of reducing the height of the solder ball 160 mounted on the external circuit board. That is, the height of the first encapsulation body 151 is lower than the final reduced height of the solder balls 160. For example, in case of using solder balls with a diameter of 450 mm, which are recently used on CSPs, the original height of the solder ball 160 is 375 mm. However, the solder ball 160 is reduced to a height of 300 mm after being mounted on the external circuit device. Thus, it is preferable to make the height of the first encapsulation body 151 from the upper surface of the tape circuit board 120 less than 200 mm.

The groove 130 can be formed in a ring shape around the window 122, preventing the liquid encapsulant of the first encapsulation body 151 from overflowing toward the solder ball pads 126. The groove 130 is preferably sharply stepped down from the upper surface of the protection layer 125 and thus blocks the encapsulant from overflowing, for example, due to surface tension.

Because the encapsulant does not coat the exposed circuit patterns 123, if the groove 130 is deeply formed so as to completely expose the circuit patterns 123, the packages may be detected as failures in reliability tests such as thermal humidity bias (THP) processed in a high temperature of about 85° C. and high humidity of about 85%. If the exposed circuit patterns in the groove are in high temperature and high humidity conditions, the exposed circuit patterns corrode, thereby causing electrical shorts. Therefore, the groove 130 is formed so that the circuit patterns 123 are not exposed through the groove 130.

FIGS. 5 to 10 show each step of a manufacturing method of a tape circuit board in accordance with a first embodiment of the present invention.

As shown in FIG. 5, the polyimide tape 121 having the circuit patterns 123 on the upper surface is prepared. A Cu or an Au foil is attached to the upper surface of the polyimide tape 121, and etched using photolithography. Then, the circuit patterns 123 having the board pads 124 and the solder ball pads 126 are formed. The window 122 is formed in the center of the polyimide tape 121. The window 122 has a predetermined dimension so as to expose the electrode pads of the semiconductor chip. In this embodiment of the present invention, the polyimide tape is about 75 mm thick and the Cu or the Au foil of the circuit patterns is about 18 mm thick.

As shown in FIG. 6, the protection layer 125 is formed. The protection layer 125 is formed on the upper surface of the polyimide tape 121 except for the window 122 and the board pads 124 by coating photo solder resist (PSR) with a screen-printing method. The photo solder resist with a viscosity of about 220 dpa is screen-printed about 25 mm to 45 mm thick.

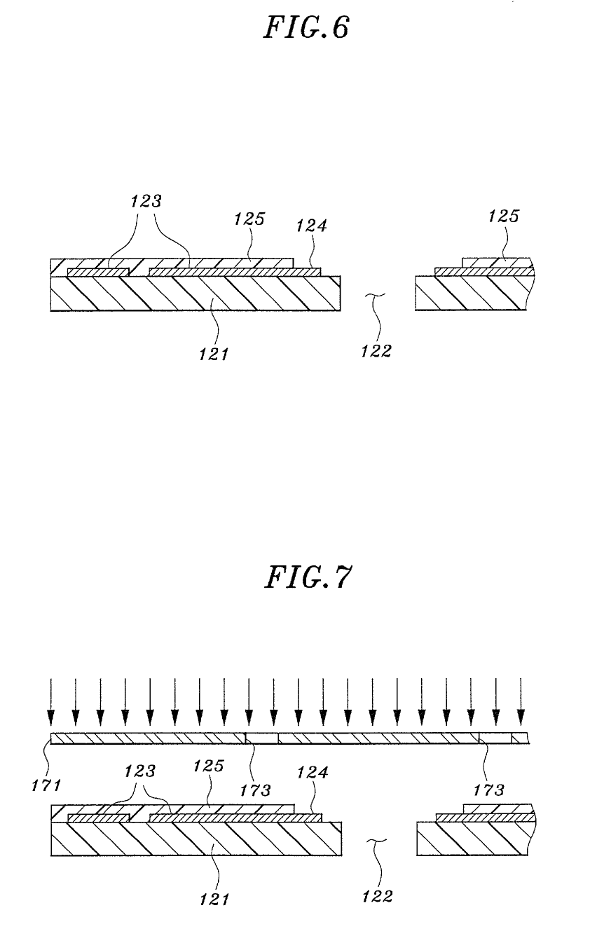

As shown in FIG. 7, a groove region of the protection layer 125 is exposed. The groove region of the protection layer 125 is exposed using a first mask 171 with an opening 173. At this time, a light of about 210 mJ/cm2 to 350 mJ/cm2 is radiated for approximately 3 sec. In order to prevent the encapsulant from overflowing, the groove region of the protection layer 125 has a ring shape and surrounds the window 122. The opening 173 of the first mask 171 corresponds to this ring-shaped groove region.

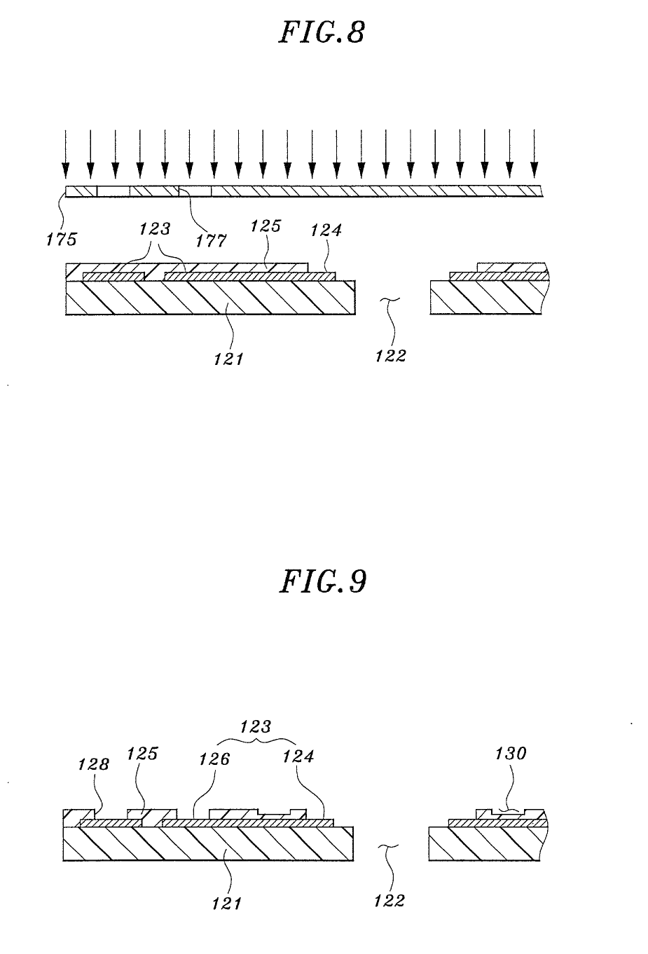

As shown in FIG. 8, via hole regions of the protection layer 125 are exposed. The via hole regions of the protection layer 125 are exposed using a second mask 175 with a plurality of openings 177. At this time, a light of about 210 mJ/cm2 to 350 mJ/cm2 is radiated for approximately 5 sec. Each of the openings 177 corresponds to a respective one of the via hole regions. Preferably, the size of opening 177 of the second mask 175 is less than that of the solder ball pad.

As shown in FIG. 9, the protection layer 125 is developed. Thereby, the exposed groove region of the protection layer 125 is removed to form the groove 130 and the exposed via hole regions of the protection layer 125 are removed to form via holes 128 for exposing the solder ball pads 126. The groove 130 has a predetermined depth so that the circuit patterns 123 are not exposed through the groove 130. The groove 130 has a predetermined width so that the groove 130 is disposed between the board pads 124 and the closet solder ball pads 126 to the window.

The time for exposing the groove region (3 sec.) is shorter than the time for exposing the via hole regions (5 sec.). Thereby, the groove region of the protection layer 125 is incompletely removed and the circuit patterns 123 are not exposed by the groove 130.

As shown in FIG. 10, the plating layer 129 is formed. In order to improve the bondability of the board pads 124 and the solder ball pads 126, the plating layer 129 made of a metal such as Ni or Au is formed on the board pads 124 and the solder ball pads 126. Then, the elastomer 127 (FIGS. 2 and 3) is preferably attached to the lower surface of the polyimide tape 121.

Although the above-described embodiment of the present invention forms the groove 130 by partially removing, e.g., half-etching the protection layer 125 on the polyimide tape 121 using photolithography, the groove 130 may be of various shapes and be formed by other methods.

FIGS. 11 to 14 show various stages of a manufacturing method of a tape circuit board in accordance with another embodiment of the present invention.

As shown in FIG. 11, the polyimide tape 121 having the circuit patterns 123 on the upper surface is prepared. The protection layer 125 is formed on the upper surface of the polyimide tape 121 except for the window 122, the board pads 124 and the groove 130 by coating, for example, PSR by conventional techniques such as a screen-printing method. The PSR with a viscosity of about 220 dpa is screen-printed to a thickness of about 25 mm to 45 mm.

At this time, the circuit patterns 123 are initially exposed through the groove 130. However, because the PSR has a predetermined viscosity, if the width d of the groove 130 is narrow enough, (for example, approximately 30 mm to 50 mm), the PSR flows along the inner walls of the groove 130 and fills the exposed circuit patterns 123 at the bottom surface of the groove 130, thereby preventing the exposure of the circuit patterns 123. Herein, reference numeral 125a refers to the PSR that has been flowed along the inner walls of the grove 130.

Next, the photolithography step for exposing the solder ball pads and the plating layer forming step are the same as those of the embodiment of the present invention described above.

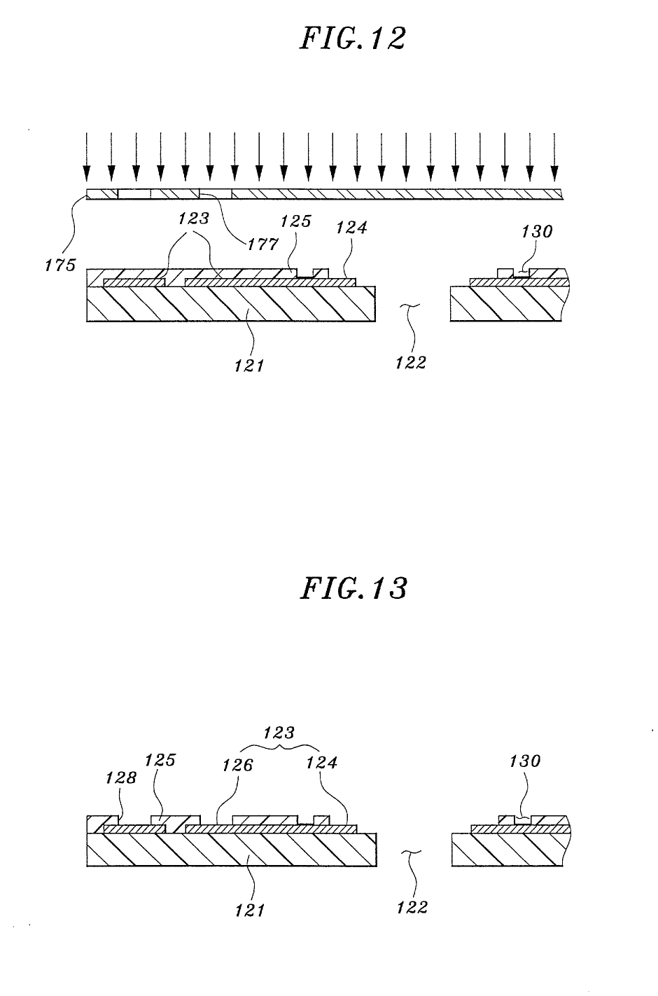

As shown in FIG. 12, via hole regions of the protection layer 125 are exposed. The via hole regions of the protection layer 125 are exposed using the second mask 175 with a plurality of the openings 177. At this time, a light of about 210 mJ/cm2 to 350 mJ/cm2 is radiated for approximately 5 sec. Each of the openings 177 corresponds to a respective one of the via hole regions. Preferably, the size of openings 177 of the second mask 175 is less than that of the solder ball pad.

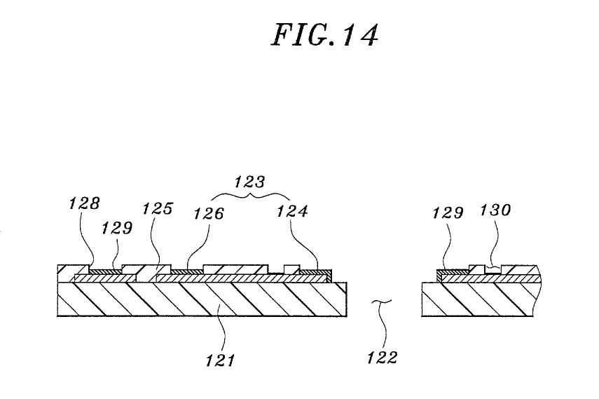

As shown in FIG. 13, the protection layer 125 is developed. Thereby, the exposed via hole regions are removed to form the via holes 128 for exposing the solder ball pads 126.

As shown in FIG. 14, the plating layer 129 is formed. In order to improve the bondability of the board pads 124 and the solder ball pads 126, the plating layer 129 made of a metal such as Ni or Au is formed on the board pads 124 and the solder ball pads 126.

Then, the elastomer 127 (FIGS. 2 and 3) is preferably attached to the lower surface of the polyimide tape 121.

A manufacturing method for a semiconductor package using the tape circuit board in accordance with the above-described embodiments of the present invention includes attaching a semiconductor chip on the lower surface of the tape circuit board, electrically connecting, e.g., wire-bonding the exposed electrode pads of the semiconductor chip to the board pads of the tape circuit board, encapsulating the wire bonding parts within the window and the side surfaces of the semiconductor chip with an encapsulant, for example, a liquid encapsulant, and attaching a solder ball to a corresponding one of the solder ball pads of the tape circuit board.

Although the preferred embodiments of the present invention employ the tape circuit board having a single-layered circuit patterns, a tape circuit board having a multi-layered circuit patterns may also be used.

Consequently, the present invention prevents the encapsulant from overflowing into the solder ball pads. The groove does not expose the circuit patterns of the polyimide tape, thereby preventing various failures due to the exposure of the circuit patterns.

The groove also can be formed in the conventional manufacturing process of the tape circuit board.

Although the preferred embodiments of the present invention have been described in detail hereinabove, it should be understood that many variations and/or modifications of the basic inventive concepts herein taught which may appear to those skilled in the art will still fall within the spirit and scope of the present invention as defined in the appended claims.

What is claimed is:

1. A semiconductor package, comprising:
a semiconductor chip with a plurality of electrode pads formed on an active surface thereof;
a tape circuit board comprising:
an insulating tape with a window formed in a center thereof;
circuit patterns formed on an upper surface of the insulating tape, the circuit patterns having a plurality of board pads adjacent the window and a plurality of conductive ball pads connected to the board pads; and
a protection layer overlying the upper surface of the insulating tape, leaving the board pads and the conductive ball pads uncovered,
wherein the active surface of the chip is attached to a lower surface of the insulating tape and the electrode pads are exposed through the window and electrically connected to board pads, and
wherein a groove formed in the protection layer extends around the window to prevent encapsulant overflow.

2. The semiconductor package of claim 1, further comprising:
a plurality of bonding wires for electrically connecting the electrode pads to the board pads through the window.

3. The semiconductor package of claim 2, further comprising:
an encapsulation body formed by encapsulating the window and the board pads with an encapsulant.

4. The semiconductor package of claim 3, further comprising:
a plurality of solder balls formed on the conductive ball pads.

5. The semiconductor package of claim 1, wherein said insulating tape is a polyimide tape.

6. The semiconductor package of claim 1, wherein the tape circuit board further comprises an elastomer on the lower surface of the insulating tape, and the active surface of the chip is attached to the elastomer.

7. The semiconductor package of claim 1, wherein the protection layer is made of photo solder resist.

8. The semiconductor package of claim 1, wherein the upper surface of the encapsulation body is lower than the top surface of the solder ball.

9. The semiconductor package of claim 1, wherein the encapsulant is a thermosetting silicon resin.

10. A method for manufacturing a semiconductor package, the method comprising:
(A) manufacturing a tape circuit board, comprising:
(1) preparing an insulating tape having a window formed in a center thereof, and circuit patterns formed on an upper surface thereof, the circuit patterns having a plurality of board pads adjacent the window and a plurality of conductive ball pads electrically connected to the board pads;
(2) forming a protection layer on the upper surface of the insulating tape except for the board pads and the conductive ball pads, wherein a groove is formed in the protection layer along a perimeter of the window by incompletely removing the protection layer so that the groove does not expose the circuit patterns; and
(3) attaching an elastomer on the lower surface of the insulating tape;
(B) attaching an active surface of a semiconductor chip to a lower surface of the elastomer in a way that electrode pads formed on the active surface of the chip are exposed through the window; and
(C) electrically connecting the electrode pads to the board pads.

11. The method of claim 10, further comprising:
(D) forming an encapsulation body by encapsulating the window and the board pads with an encapsulant, thereby protecting the electrode pads from external environments.

12. The method of claim 11, further comprising:
(E) forming solder balls on the conductive ball pads.

13. The method of claim 10, wherein the protection layer is made of photo solder resist.

14. The method of claim 10, wherein the step (B) comprises:
(1) forming a protection layer on the upper surface of the insulating tape except for the board pads;
(2) exposing a groove region of the protection layer, the groove region spaced from the board pads extending substantially around the perimeter of the window;
(3) exposing via hole regions of the protection layer, the via hole regions corresponding to the conductive ball pads; and
(4) forming a groove by developing the exposed groove region of the protection layer, and forming via holes by developing the exposed via hole regions of the protection layer.

15. The method of claim 14, wherein in step (2) the groove region is exposed by a light of 210 mJ/cm2 to 350 mJ/cm2 for approximately 3 sec. and in step (3) the via hole regions of the protective layer is exposed by a light of 210 mJ/cm2 to 350 mJ/cm2 for approximately 5 sec.

16. The method of claim 10, wherein the step (B) comprises:
(1) forming a protection layer on the upper surface of the insulating tape except for the board pads and a groove region;
(2) exposing via hole regions of the protection layer, the via hole regions corresponding to the conductive ball pads; and
(3) forming via holes by developing the exposed via hole regions of the protection layer,
wherein in sub-step (1), the photo solder resist flows into a bottom surface of the groove region.

17. The method of claim 16, wherein sub-step (1) the groove region is approximately 25 μm to 45 μm wide.

18. The method of claim 10, further comprising, after step (B), forming a plating layer on the board pads and the conductive ball pads.

19. The method of claim 11, further comprising, after step (B), forming a plating layer on the board pads and the conductive ball pads.

20. The method of claim 12, further comprising, after step (B), forming a plating layer on the board pads and the conductive ball pads.

21. The method of claim 13, further comprising, after step (B), forming a plating layer on the board pads and the conductive ball pads.

22. The method of claim 14, further comprising, after step (B), forming a plating layer on the board pads and the conductive ball pads.

23. The method of claim 15, further comprising, after the step (B), forming a plating layer on the board pads and the conductive ball pads.

24. The method of claim 10, wherein in step (D), the encapsulation body is formed by a dispensing method.

25. The method of claim 10, wherein in step (D), the encapsulant is a thermosetting silicon resin.

26. The method of claim 10, wherein step (D) further comprises encapsulating side surfaces of the chip with a liquid encapsulant.

27. A method for manufacturing a tape circuit board, the method comprising:
preparing an insulating tape having a window formed in a center thereof, and circuit patterns formed on an upper surface thereof, the circuit patterns having a plurality of board pads adjacent the window and a plurality of conductive ball pads electrically connected to the board pads; and
forming a protection layer on the upper surface of the insulating tape except for the board pads and the conductive ball pads,
wherein a groove is formed in the protection layer, the groove extending substantially around a perimeter of the window.

28. The method of claim 27, wherein the groove is formed by incompletely removing the protection layer such that the groove does not expose the circuit patterns.

29. The method of claim 27, further comprising:
attaching an adhesive on a lower surface of the insulating tape;
attaching an active surface of a semiconductor chip to a lower surface of the adhesive so that electrode pads formed on the active surface of the chip are exposed through the window; and
electrically connecting the electrode pads to the board pads.

30. The method of claim 28, wherein the adhesive is an elastomer.

31. A tape circuit board for forming a semiconductor package, comprising:
an insulating tape with a window formed in a center thereof;
circuit patterns formed on an upper surface of the insulating tape, the circuit patterns having a plurality of board pads adjacent the window and a plurality of conductive ball pads connected to the board pads; and
a protection layer overlying the upper surface of the insulating tape, leaving the board pads and the conductive ball pads uncovered,
wherein a groove in the protection layer extends substantially around a perimeter of the window to prevent encapsulant overflow.

32. The tape circuit board, wherein the groove does not expose the circuit patterns.

33. The tape circuit board of claim 30, wherein an active surface of a semiconductor chip having electrode pads formed thereon is attached to a lower surface of the insulating tape and the electrode pads are exposed through the window and electrically connected to board pads.

34. The tape circuit board of claim 30, wherein the groove is formed in a ring shape around the window.

35. A semiconductor package comprising:
a semiconductor chip with a plurality of electrode pads formed on an active surface thereof;
a tape circuit board comprising:
an insulating tape with a window formed in a center thereof,
circuit patterns formed on an upper surface of the insulating tape, the circuit patterns having a plurality of board pads adjacent the window and a plurality of conductive ball pads connected to the board pads; and
a protection layer overlying the upper surface of the insulating tape, leaving the board pads and the conductive ball pads uncovered,
wherein the active surface of the chip is attached to a lower surface of the insulating tape and the electrode pads are exposed through the window and electrically connected to board pads, and
wherein a groove is formed in the protection layer and formed in a substantially ring shape.

36. The semiconductor package of claim 34, further comprising an elastomer on a lower surface of the insulating tape,
wherein the active surface of a semiconductor chip attached to a lower surface of the elastomer so that electrode pads formed on the active surface of the chip are exposed through the window.
